(19) United States
(12) Patent Application Publication
(10) Pub. No.: US 2004/0214468 A1
(43) Pub. Date: Oct. 28, 2004

(54) Electrical connector

(76) Inventors: Rwei Ching Chang, Taipei Hsien (TW); Ching-Liang Tu, Taipei Hsien (TW)

Correspondence Address: Leong C. Lei, PMB#1008, 1867 Ygnacio Valley Rd., Walnut Creek, CA, 94598, US

(21) Appl. No.: 10/819,279

(22) Filed: Apr. 7, 2004

(30) Foreign Application Priority Data
Apr. 22, 2003 (TW) 92109400

(51) Int. Cl. H05K 1/00

(52) U.S. Cl. 439/342

(57) ABSTRACT

An electrical connector which includes a seat integrally made of plastic and formed with a plurality of through holes, a plurality of metal terminals each fitted in a respective one of the through holes of the seat and provided with a tail, and a base board used as a conductive medium between an electrical connector and a printed circuit board to provide a closed circuit, wherein the base board has an upper surface in contact with the electrical connector, a lower surface in contact with the printed circuit board, and a plurality of conductive members arranged between the upper and lower surfaces, whereby the possibility of unstable connection between the terminal and the solder ball can be eliminated.

### BACKGROUND OF THE INVENTION

(a) Field of the Invention

This invention is related to an electrical connector, and in particular to a high density electrical connector with solder ball mounting technology.

(b) Description of the Prior Art

Computers, communication and consumer electronic products are popular and widely spread in the present consumer market. An increased data transmission capacity and signal transmission speed is greatly desired, particularly for portable devices. The devices must be compact in size, but their functions have to be increased so that electronic components such as electronic connectors must be of high density and low in profile. In addition, in order to increase the number of terminals, it is necessary to reduce the distance between terminals. Hence, the electrical connector manufacturers generally use SMT (surface-mount technology) for connections, because SMT can reduce the distance between terminals, thereby achieving the purpose of high density and low profile requirements.

If the electroplating material on the terminal tail of electrical connectors is different, the connection between the terminal tail and the solder assistant agent will be difficult to control. For example, if the terminal is gold-plated, the solder ball will melt when heated. Because of the anti-oxidation property of gold, the smooth surface with the activation of the solder assisting agent will make the melted tin go upwardly along the terminal tail, thereby causing the so-called wicking phenomenon. As a consequence, it will be very difficult to put soldering with the electrical connector.

If the terminal tail is plated with nickel, since nickel is unstable and is easily oxidized, the oxidized layer will be very difficult to remove. Although there is solder assisting agent between the terminal tail and the solder ball, the thickness of the oxidized layer is uneven, thereby making an incomplete activation, and therefore easily causing empty soldering and short-circuiting. So, the signals cannot be transmitted to the printed circuit board via the solder balls. The soldering technology adopted by electrical connectors can be referred from a U.S. Pat. No. 6,095,842.

Therefore, it is an object of the present invention to provide an electrical connector which can eliminate the possibility of unstable connection between the terminal and the solder ball.

### SUMMARY OF THE INVENTION

This invention is related to an improvement in the structure of an electrical connector.

It is the primary object of the present invention to provide an electrical connector which includes a seat integrally made of plastic and formed with a plurality of through holes, a plurality of metal terminals each fitted in a respective one of the through holes of the seat and provided with a tail, and a base board used as a conductive medium between an electrical connector and a printed circuit board to provide a closed circuit, wherein the base board has an upper surface in contact with the electrical connector, a lower surface in contact with the printed circuit board, and a plurality of conductive members arranged between the upper and lower surfaces, whereby the possibility of unstable connection between the terminal and the solder ball can be eliminated.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is an exploded view of the present invention;

FIG. 2 is a sectional view of the present invention;

FIG. 3 is an enlarged view of a portion of FIG. 2;

FIG. 4 is a sectional view of another preferred embodiment of the present invention; and

FIG. 5 is an enlarged view of a portion of FIG. 4.

### DETAILED DESCRIPTION OF THE PREFERRED EMBODIMENT

The following descriptions are of exemplary embodiments only, and are not intended to limit the scope, applicability or configuration of the invention in any way Rather, the following description provides a convenient illustration for implementing exemplary embodiments of the invention. Various changes to the described embodiments may be made in the function and arrangement of the elements described without departing from the scope of the invention as set forth in the appended claims.

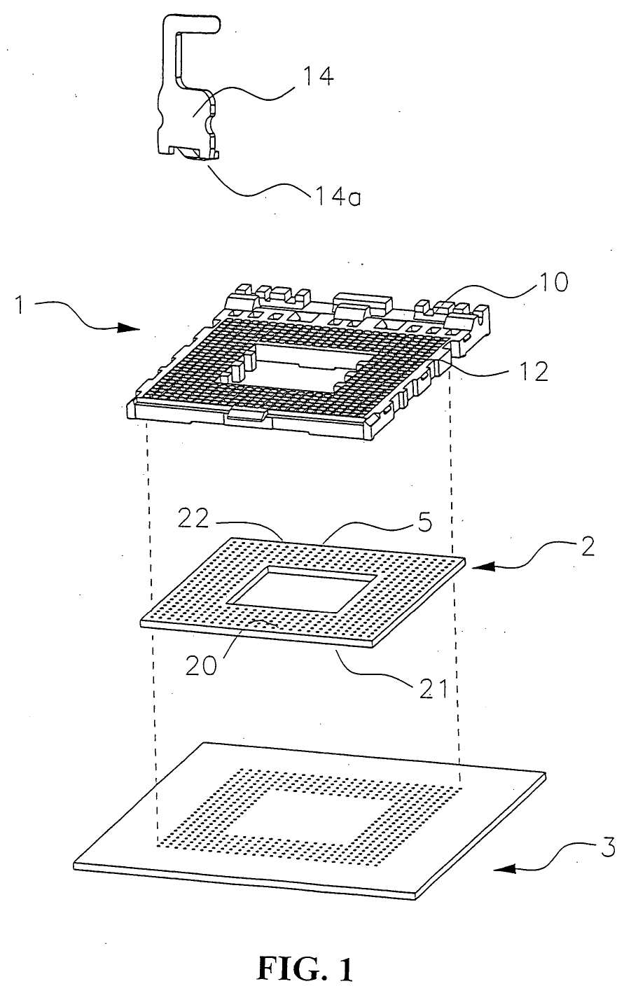

With reference to the drawings and in particular to FIG. 1 thereof, the electrical connector 1 according to the present invention is used for connecting a CPU (not shown). The electrical connector 1 comprises a seat 10 integrally made of plastic and formed with a plurality of vertical through holes 12, and a plurality of metal terminals 14 fitted in a respective one of the through holes 12. Each of the terminals 14 is provided with a tail 14a which is a sheet member extending outwardly from the lower end of the terminal 14.

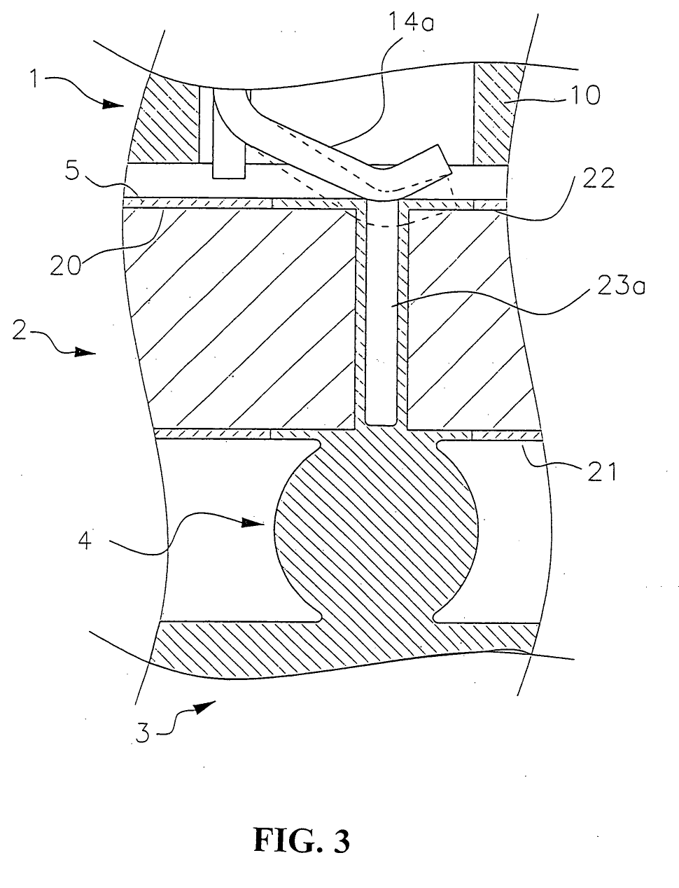

A base board 2 having an upper surface 20 and a lower surface 21 is mounted on the bottom of the seat 10. The base board 2 is provided with a plurality of conductive members 23a extending through the upper and lower surfaces 20 and 21. On the upper surface 20 of the base board 2 is mounted a pad 22 for receiving the tail 14a of the terminal 14 (see FIG. 3). The conductive members 23 are arranged so that the tail 14a of the terminals 14 is in contact with a respective one of the conductive members 23. The base board 2 can be conveniently made by printed circuit board manufacturing process.

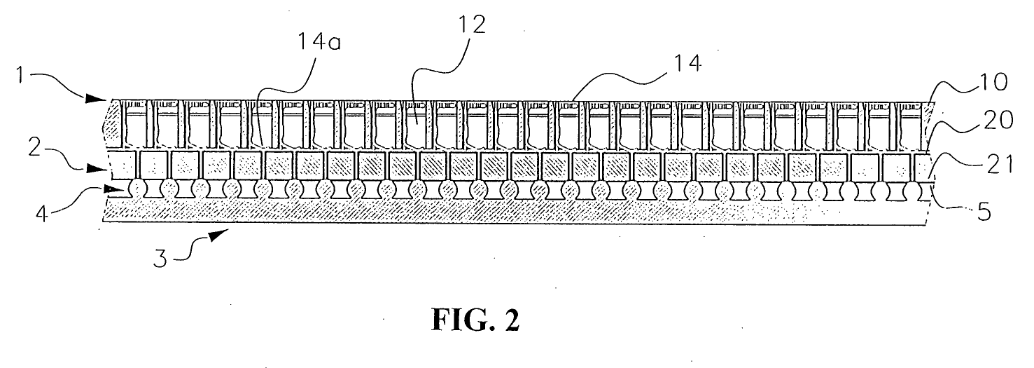

FIG. 2 is a sectional view of the present invention. As shown, the electrical connection 1 is mounted on the base board 2, but not directly soldered on a printed circuit board 3. As the tail 14a is a sheet member, the tail 14a can be in flat face contact with the pad 22 on the upper surface 20 of the base board 2. A plurality of solder balls 4 are soldered between the lower surface 21 of the base board 2 and the printed circuit board 3. Before the solder balls 4 are joined with solder to the lower surface 21 of the base board 2 and the printed circuit board 3, a layer of insulation material 5 is coated on the lower surface 21 of the base board 2 and the printed circuit board 3 for giving assistance to the positioning of the solder balls 4.

Consequently, when the terminal 4 receives signals from the CPU, the signals will be transmitted to the printed circuit board 3 through the conductive member 23a fitted in the base board 2. Hence, it is unnecessary for the terminal 4 to be in contact with the solder ball 4 thereby obviating the possibility of unstable connection between the terminal 4 and the solder ball 4.

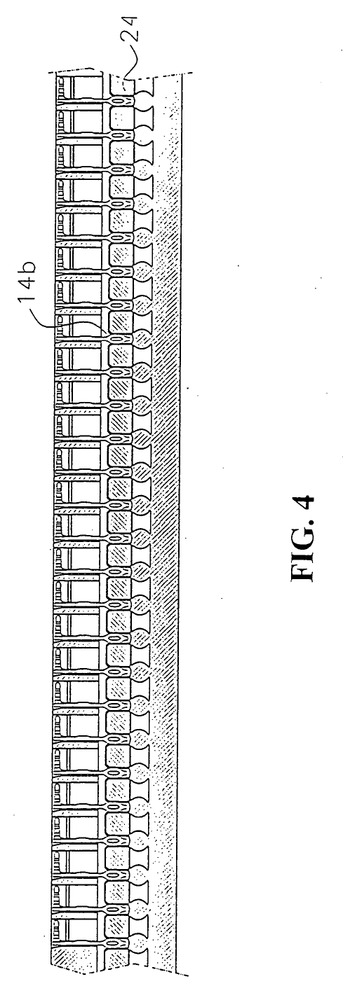

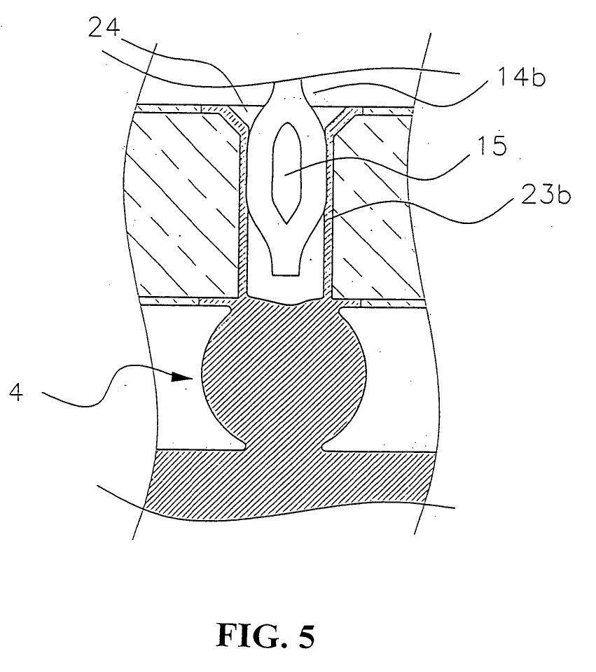

FIGS. 4 and 5 show a second preferred embodiment of the present invention. As illustrated, the terminal has a downwardly extending tail 14b which is adapted to be fitted into a counter sink 24 which goes through the base board. The counter sink 24 has a diameter equal to or smaller than the tail 14b of the terminal. The tail 14b is formed with a center hole 15 thereby providing resiliency thereto, so that the tail 14b can be firmly fitted in the counter sink 24. The inner surface of the counter sink 24 is coated with a layer of conductive material 23b such as tin, copper foil, or the like.

When the tail 14b of the terminal is inserted into the counter sink 24 of the base board, the tail 14b will be slightly deformed thereby providing a firm connection between the tail 14b and the conductive material 23b. As the terminal receives signals from a CPU, the signals will be transmitted to the tail 14b of the terminal which will then be transmitted to the printed circuit board via the conductive material 23b. As shown in FIG. 5, the tail 14b is designed so that the lower end of the tail 14b will not be in contact with the solder ball 4 thereby preventing the possibility of unstable connection between the terminal and the solder ball 4.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. An electrical connector comprising a base board with a plurality of conductive members used as conductive medium between said connector and a printed circuit board thereby providing a closed circuit.

2. An electrical connector comprising:
a seat integrally made of plastic and formed with a plurality of through holes;
a plurality of metal terminals each fitted in a respective one of said through holes of said seat and provided with a tail.

3. The electrical connector as claimed in claim 2, wherein said tail extends downwardly from said terminals.

4. The electrical connector as claimed in claim 2, wherein said tail is a sheet member extending outwardly from a lower end of said terminals.

5. The electrical connector as claimed in claim 1, wherein said base board is made by printed circuit board manufacturing process.

6. A base board used as a conductive medium between an electrical connector and a printed circuit board to provide a closed circuit, comprising:
an upper surface in contact with said electrical connector;
a lower surface in contact with said printed circuit board;
a plurality of conductive members arranged between said upper and lower surfaces.

7. The base board as claimed in claim 6, wherein said upper surface of said base board is provided with a pad.

8. The base board as claimed in claim 6, wherein said base board is made by printed circuit board manufacturing process.

9. The base board as claimed in claim 6, wherein each of said conductive members is mounted between said upper and lower surfaces of said base board thereby connecting with said pad on said upper surface and a solder ball joined to said lower surface with solder thereby providing a closed circuit.

10. The base board as claimed in claim 6, wherein said conductive members are made of copper foil.

11. The base board as claimed in claim 6, wherein said base board is provided with a plurality of counter sinks which goes through said upper and lower surfaces.

12. The base board as claimed in claim 11, wherein said counter sink is coated with a layer of conductive material.

13. The base board as claimed in claim 6, wherein said counter sink has a diameter which is equal to or smaller than a tail of said terminal.

14. The base board as claimed in claim 12, wherein said conductive members have a tail fitted in a respective one of said counter sinks to be in contact with said conductive material thereby indirectly contacting solder balls joined to said lower surface with solder.

15. The base board as claimed in claim 12, wherein said conductive material is made of tin.
